(19) United States
(12) Patent Application Publication
(10) Pub. No.: US 2026/0068132 A1
(43) Pub. Date: Mar. 5, 2026

(54) SEMICONDUCTOR DEVICE AND MANUFACTURING METHOD FOR SAME

(71) Applicant: Fujian Jinhua Integrated Circuit Co., Ltd., Fujian (CN)

(72) Inventors: Janbo ZHANG, Fujian (CN); Yirong XU, Fujian (CN); Youchang WANG, Fujian (CN)

(73) Assignee: Fujian Jinhua Integrated Circuit Co., Ltd., Fujian (CN)

(21) Appl. No.: 18/988,903

(22) Filed: Dec. 20, 2024

(30) Foreign Application Priority Data
Sep. 5, 2024 (CN) 202411245364.6

(51) Int. Cl. H10B 12/00

(52) U.S. Cl. CPC H10B 12/34; H10B 12/053

(57) ABSTRACT

The present disclosure provides a semiconductor device and a manufacturing method for same. The semiconductor device includes: a substrate; a gate trench; a gate dielectric layer, covering an inner surface of the gate trench; and a gate structure, being disposed on the gate dielectric layer and filling the gate trench, where the gate structure includes a metal layer and a conductive layer; the metal layer includes: a plurality of first grains; and a plurality of second grains, being disposed on the first grains, where the first grains and the second grains contain a same metallic element, and grain sizes of the second grains are smaller than grain sizes of at least a portion of the first grains; the conductive layer is isolated from the second grains with oxygen, and a side of the oxygen away from the first grains is in contact with the conductive layer.

### CROSS-REFERENCE TO RELATED APPLICATIONS

This application claims priority to Chinese Patent Application No. 202411245364.6, filed on Sep. 5, 2024, which is hereby incorporated by reference in its entirety.

### TECHNICAL FIELD

The present disclosure relates to the field of semiconductor technology, and in particular to a semiconductor device and a manufacturing method for same.

### BACKGROUND

With the continuous development and advancement of semiconductor manufacturing technologies, the application scope of semiconductor devices has expanded increasingly, and feature sizes of the semiconductor devices have been constantly scaling. A semiconductor device typically includes a gate structure which is used to control other semiconductor devices within the semiconductor device. However, the semiconductor device is often prone to a gate induced drain leakage phenomenon, resulting in poor performance of the semiconductor device.

### SUMMARY

In view of the above issues, embodiments of the present disclosure provide a semiconductor device and a manufacturing method for same, to enhance performance of semiconductor devices.

According to some embodiments, a first aspect of the present disclosure provides a semiconductor device, comprising: a substrate; a gate trench, being disposed in the substrate; a gate dielectric layer, being disposed in the substrate and covering an inner surface of the gate trench; and a gate structure, being disposed on the gate dielectric layer and filling the gate trench, where the gate structure comprises a metal layer and a conductive layer; the metal layer comprises: a plurality of first grains; and a plurality of second grains, being disposed on the first grains, where the first grains and the second grains contain a same metallic element, and grain sizes of the second grains are smaller than grain sizes of at least a portion of the first grains; the conductive layer is disposed on the second grains; where the conductive layer is isolated from the second grains with oxygen, and a side of the oxygen away from the first grains is in contact with the conductive layer.

The semiconductor device according to the embodiments of the present disclosure comprises a substrate, a gate trench disposed in the substrate, a gate dielectric layer disposed in the substrate and covering an inner surface of the gate trench, and a gate structure disposed on the gate dielectric layer and filling the gate trench. The gate structure comprises a metal layer and a conductive layer, where the metal layer comprises a plurality of first grains and a plurality of second grains disposed on the first grains. The first grains and the second grains contain a same metallic element to ensure the electrical performance of the metal layer. Grain sizes of the second grains are smaller than grain sizes of at least a portion of the first grains, avoiding too large grain sizes of the second grains, thus facilitating formation of a film layer thereon. The conductive layer is isolated from the second grains with oxygen, and a side of the oxygen away from the first grains is in contact with the conductive layer, avoiding the direct contact between the second grains and the conductive layer, and thus preventing a reaction between the conductive layer and the metal layer during the subsequent thermal processing to reduce the gate induced drain leakage, thereby, improving the electrical characteristics of the gate structure, and enhancing the performance of the semiconductor device.

According to some embodiments, a second aspect of the present disclosure provides a manufacturing method for a semiconductor device. The manufacturing method comprises: providing a substrate, where a gate trench is formed in the substrate, and an inner surface of the gate trench is covered with a gate dielectric layer; forming a gate structure, the gate structure being disposed on the gate dielectric layer and filling the gate trench, and the gate structure comprising a metal layer and a conductive layer; where the metal layer comprises a plurality of first grains and second grains, the second grains being disposed on the first grains, the first grains and the second grains containing a same metallic element, and grain sizes of the second grains being smaller than grain sizes of at least a portion of the first grains; and where the conductive layer is disposed on the second grains, where the conductive layer is isolated from the second grains with oxygen, and a side of the oxygen away from the first grains is in contact with the conductive layer.

In the manufacturing method for a semiconductor device according to the embodiments of the present disclosure, the first grains and the second grains contain a same metallic element to ensure the electrical performance of the metal layer. Grain sizes of the second grains are smaller than grain sizes of at least a portion of the first grains, avoiding too large grain sizes of the second grains, thus facilitating formation of a film layer thereon. The conductive layer is isolated from the second grains with oxygen, and a side of the oxygen away from the first grains is in contact with the conductive layer, avoiding the direct contact between the second grains and the conductive layer, and thus preventing a reaction between the conductive layer and the metal layer during the subsequent thermal processing to reduce the gate induced drain leakage, thereby, improving the electrical characteristics of the gate structure, and enhancing the performance of the semiconductor device.

### BRIEF DESCRIPTION OF DRAWINGS

FIG. 1 is a schematic structural diagram of a semiconductor device according to an embodiment of the present disclosure.

FIG. 2 is a cross-sectional schematic diagram from A-A section in FIG. 1.

FIG. 3 is a cross-sectional schematic diagram from B-B section in FIG. 1.

FIG. 4 is another cross-sectional schematic diagram from A-A section in FIG. 1.

FIG. 5 is a flowchart of a manufacturing method for a semiconductor device according to an embodiment of the present disclosure.

FIG. 6 is a cross-sectional schematic diagram of a substrate according to an embodiment of the present disclosure.

FIG. 7 is a cross-sectional schematic diagram when first grains are formed according to an embodiment of the present disclosure.

FIG. 8 is another cross-sectional schematic diagram when first grains are formed according to an embodiment of the present disclosure.

FIG. 9 is a localized enlarged diagram of area D in FIG. 8.

FIG. 10 is a cross-sectional schematic diagram when second grains are formed according to an embodiment of the present disclosure.

FIG. 11 is another cross-sectional schematic diagram when second grains are formed according to an embodiment of the present disclosure.

FIG. 12 is a localized enlarged diagram of area D in FIG. 11.

FIG. 13 is a cross-sectional schematic diagram when a conductive layer is formed according to an embodiment of the present disclosure.

FIG. 14 is another cross-sectional schematic diagram when a conductive layer is formed according to an embodiment of the present disclosure.

### DESCRIPTION OF EMBODIMENTS

In related technologies, metal and polysilicon in a gate structure tend to blend during subsequent thermal processing, forming a metal silicide layer, which increases the gate induced drain leakage current and affects performance of a semiconductor device. Therefore, embodiments of the present disclosure provide a semiconductor device and a manufacturing method for same, which utilize oxygen to isolate a metal layer and a conductive layer, avoiding direct contact between second grains and the conductive layer, and thus preventing a reaction between the conductive layer and the metal layer during the subsequent thermal processing, thereby, reducing the gate induced drain leakage and enhancing the performance of the semiconductor device.

In order to make the foregoing objectives, features and advantages of the embodiments of the present disclosure clearer and more intelligible, the technical solutions of the embodiments of the present disclosure will be described hereunder clearly and comprehensively in conjunction with the accompanying drawings of the embodiments of the present disclosure. Apparently, the described embodiments are merely some of, rather than all of the embodiments of the present disclosure. Based on the embodiments in the present disclosure, all other embodiments obtained by those of ordinary skill in the art without creative efforts shall fall within the protection scope of present disclosure.

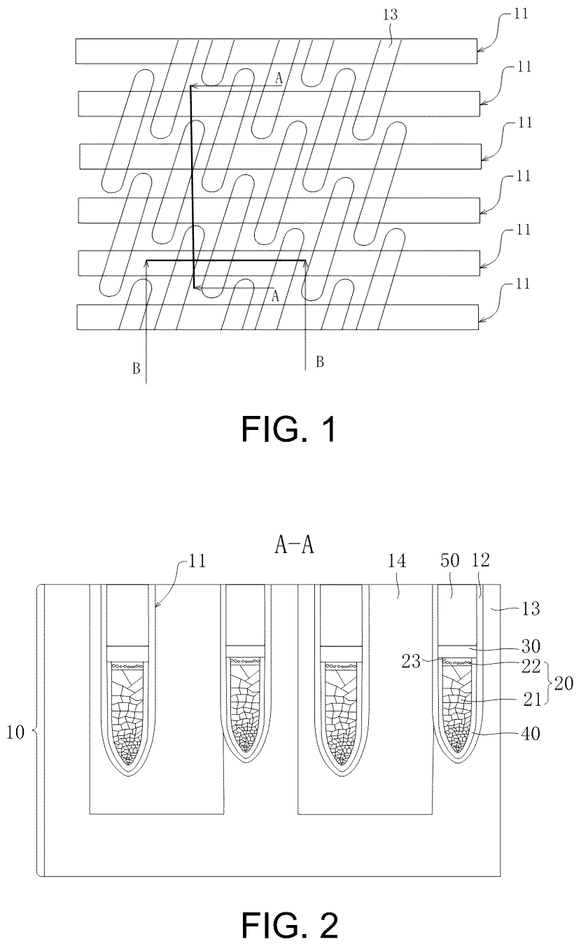

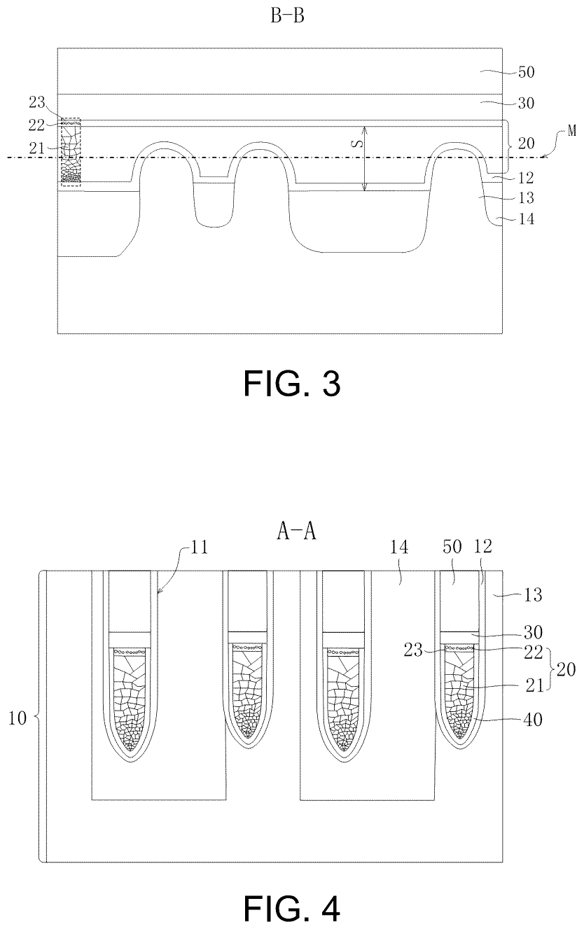

With reference to FIG. 1 to FIG. 4, FIG. 1 is a schematic structural diagram of a semiconductor device according to an embodiment of the present disclosure; FIG. 2 is a cross-sectional schematic diagram from A-A section in FIG. 1; FIG. 3 is a cross-sectional schematic diagram from B-B section in FIG. 1; and FIG. 4 is another cross-sectional schematic diagram from A-A section in FIG. 1.

An embodiment of the present disclosure provides a semiconductor device which, for example, is a dynamic random access memory. The semiconductor device comprises a substrate 10, a gate trench 11, a gate dielectric layer 12, and a gate structure. The substrate 10 can be a semiconductor substrate, such as a silicon substrate, a germanium substrate, a silicon-germanium substrate, a silicon on insulator substrate, a silicon carbide substrate, a gallium nitride substrate or the like.

The substrate 10 further comprises a plurality of active areas 13 and an isolation structure 14 isolating the active areas 13. The active area 13 comprises a source region, a drain region, and a channel region. The isolation structure 14 is used to define the active areas 13 such that the plurality of active areas 13 are disposed spaced apart from each other. The isolation structure 14 is, for example, a shallow trench isolation structure.

Further disposed within the substrate 10 is a gate trench 11. There can be a plurality of gate trenches 11, the plurality of gate trenches 11 being arranged spaced apart. As an example, the gate trench 11 extends through the active areas 13 and the isolation structure 14. Portions of the active area 13 disposed at two sides of the gate trench 11 form, respectively, a source region and a drain region, and a portion of the active area 13 disposed at a bottom of the gate trench 11 forms a channel region, where two ends of the channel region are respectively connected to the source region and the drain region.

The gate dielectric layer 12 is disposed in the substrate 10 and covers an inner surface of the gate trench 11. The gate dielectric layer 12 is in contact with the gate trench 11 and is adapted to the shape of the gate trench 11, forming a substantially uniformly thick film layer. The gate dielectric layer 12 does not fill up the gate trench 11, and the gate dielectric layer 12 disposed in the gate trench 11 also encloses to form a trench-like shape. The gate dielectric layer 12 can be made of an insulating material, such as silicon oxide.

Further reference is made to FIG. 1 to FIG. 3, the gate structure is disposed on the gate dielectric layer 12 and fills the gate trench 11. The gate structure is filled at the bottom of the gate trench 11, and a top surface of the gate structure is lower than a top surface of the substrate 10. The gate structure comprises a metal layer 20 and a conductive layer 30. The metal layer 20 comprises a plurality of first grains 21 and a plurality of second grains 22, the second grains 22 being disposed on the first grains 21.

In some examples, as shown in FIG. 2, grain sizes of first grains 21 away from the second grains 22 are smaller than grain sizes of first grains 21 close to the second grains 22. The first grains 21 away from the second grains 22 is closer to the bottom of the gate trench 11, and since the size of the bottom of the gate trench 11 is relatively small, these first grains 21 with smaller grain sizes can be more suitable to fill the bottom of the gate trench 11.

Grain sizes of the first grains 21 gradually increase along a direction approaching the second grains 22. The direction approaching the second grains 22 is also a direction distancing from the bottom of the gate trench 11. The closer to the second grains 22, the larger the grain sizes of the first grains 21, thus, the grain sizes of the plurality of first grains 21 change gradually, providing good transition among the plurality of first grains 21.

The second grains 22 and the first grains 21 contain a same metallic element. In some examples, both the first grains 21 and the second grains 22 contain a tungsten element, providing good electrical characteristics for the metal layer 20. The grain sizes of the second grains 22 are smaller than grain sizes of at least a portion of the first grains 21, avoiding too large grain sizes of the second grains 22, thus allowing for a relatively dense arrangement and good planarity of the plurality of second grains 22, and facilitating formation of a film layer (such as the conductive layer 30) thereon.

As an example, the grain sizes of the second grains 22 are smaller than the grain sizes of all the first grains 21 in whole. As another example, the grain sizes of the second grains 22 are smaller than grain sizes of first grains 21 close to the second grains 22 and larger than grain sizes of first grains 21 away from the second grains 22. In this way, the grain sizes of the second grains 22 are larger than the grain sizes of the first grains 21 at the bottom of the gate trench 11, avoiding too small grain sizes of the second grains 22, and facilitating formation of the second grains 22. Meanwhile, the grain sizes of the second grains 22 are smaller than the grain sizes of the first grains 21 at the top of the gate trench 11, avoiding too large grain sizes of the second grains 22, and facilitating formation of a film layer thereon.

In some specific implementations, a first spacing S is provided between the second grains 22 and the isolation structure 14, and grain sizes of first grains 21 having a distance from the isolation structure 14 greater than or equal to a second spacing are larger than the grain sizes of the second grains 22, the second spacing being half of the first spacing. No limitation is imposed on the relationship between grain sizes of first grains 21 having a distance from the isolation structure 14 smaller than the second spacing, and the grain sizes of the second grains 22.

As shown in FIG. 3, the first spacing is provided between the surfaces facing each other of the second grains 22 and the isolation structure 14, the first spacing being indicated with S in FIG. 3. Considering an interface (indicated with M in FIG. 3) that is above the isolation structure 14 by a distance of half of the first spacing, the distance from the interface M to the isolation structure 14 is namely the second spacing. The grain sizes of the first grains 21 disposed on a side of the interface M away from the isolation structure 14 are larger than the grain sizes of the second grains 22.

Further reference is made to FIG. 2 and FIG. 3, oxygen 23 is provided on a side of the second grains 22 away from the first grains 21, meaning that the oxygen 23 is at least disposed on the second grains 22. As an example, with reference to FIG. 4, the second grains 22 are surrounded by oxygen 23 to avoid a contact between the side of the second grains 22 away from the first grains 21 and other film layers, thereby reducing or avoiding reactions between the other film layers and the second grains 22, and ensuring the performance of the metal layer 20. Here, the oxygen 23 refers to oxygen atoms, oxygen molecules, oxygen elements, or the like, which is not limited herein.

The conductive layer 30 is disposed on the second grains 22. For example, the conductive layer 30 is made of a material comprising polysilicon. The second grains 22 can be in the shape of an ellipse or other irregular shapes. The conductive layer 30 is isolated from the second grains 22 with the oxygen 23, and a side of the oxygen 23 away from the first grains 21 is in contact with the conductive layer 30. Using the oxygen 23 to isolate the second grains 22 from the conductive layer 30 avoids the direct contact between the second grains 22 and the conductive layer 30, namely avoiding the direct contact between the metal layer 20 and the conductive layer 30, thus preventing the formation of metal silicides during the subsequent thermal processing, and reducing the gate induced drain leakage, thereby, improving the electrical characteristics of the gate structure, and enhancing the performance of the semiconductor device.

Further reference is made to FIG. 2 and FIG. 3, the semiconductor device further comprises a metal nitride layer 40 which is, for example, a titanium nitride layer. The metal nitride layer 40 is disposed between the gate dielectric layer 12 and the metal layer 20 to isolate the gate dielectric layer 12 from the metal layer 20, preventing the metal layer 20 from diffusing into the gate dielectric layer 12 and ensuring the performance of the gate dielectric layer 12. The metal nitride layer 40 is also in contact with the conductive layer 30. For example, the conductive layer 30 is also disposed on the metal nitride layer 40.

The semiconductor device further comprises an insulating cap layer 50 to avoid an electric connection between a top surface of the gate structure and other film layers, ensuring the performance of the semiconductor device. The insulating cap layer 50 is filled within the gate trench 11 and disposed on a side of the conductive layer 30 away from the metal layer 20. The insulating cap layer 50 is disposed atop the conductive layer 30, a top surface of the insulating cap layer 50 is at least flush with a top surface of the substrate 10, and the insulating cap layer 50 is made of a material comprising silicon nitride, or the like.

The semiconductor device according to the embodiments of the present disclosure comprises a substrate 10, a gate trench 11 disposed in the substrate 10, a gate dielectric layer 12 disposed in the substrate 10 and covering an inner surface of the gate trench 11, and a gate structure disposed on the gate dielectric layer 12 and filling the gate trench 11. The gate structure comprises a metal layer 20 and a conductive layer 30, where the metal layer 20 comprises a plurality of first grains 21 and a plurality of second grains 22 disposed on the first grains 21. The first grains 21 and the first grains 22 contain a same metallic element to ensure the electrical performance of the metal layer 20. Grain sizes of the second grains 22 are smaller than grain sizes of at least a portion of the first grains 21, avoiding too large grain sizes of the second grains 22, thus facilitating formation of a film layer thereon. The conductive layer 30 is isolated from the second grains 22 with oxygen 23, and a side of the oxygen 23 away from the first grains 21 is in contact with the conductive layer 30. Using the oxygen 23 to isolate the second grains 22 from the conductive layer 30 avoids the direct contact between the second grains 22 and the conductive layer 30, thus preventing a reaction between the conductive layer 30 and the metal layer 20 during the subsequent thermal processing to reduce the gate induced drain leakage, thereby, improving the electrical characteristics of the gate structure, and enhancing the performance of the semiconductor device.

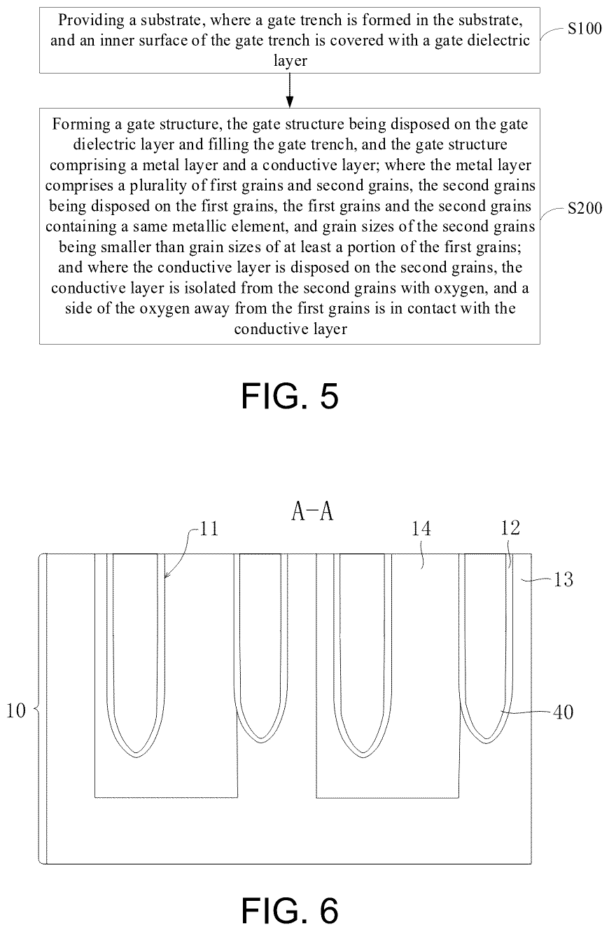

An embodiment of the present disclosure further provides a manufacturing method for a semiconductor device. Reference is made to FIG. 5 which is a flowchart of a manufacturing method for a semiconductor device according to an embodiment of the present disclosure. The manufacturing method can specifically include the steps as follows.

Step S100: providing a substrate, where a gate trench is formed in the substrate, and an inner surface of the gate trench is covered with a gate dielectric layer.

Reference is made to FIG. 6 which is a cross-sectional schematic diagram of a substrate according to an embodiment of the present disclosure. The substrate 10 comprises a semiconductor substrate which is, for example, a silicon substrate, a germanium substrate, a silicon-germanium substrate, a silicon on insulator substrate, a silicon carbide substrate, a gallium nitride substrate or the like. The substrate 10 comprises a plurality of active areas 13, and an isolation structure 14 isolating the active areas 13. The isolation structure 14 is used to define the active areas 13 such that the plurality of active areas 13 are disposed spaced apart from each other. As an example, the isolation structure 14 is a shallow trench isolation structure.

A gate trench 11 is formed in the substrate 10, for example, formed through etching. There can be a plurality of gate trenches 11, the plurality of gate trenches 11 being arranged spaced apart. The gate trench 11 extends through the active areas 13 and the isolation structure 14. Portions of the active area 13 disposed at two sides of the gate trench 11 form, respectively, a source region and a drain region, and a portion of the active area 13 disposed at a bottom of the gate trench 11 forms a channel region, where two ends of the channel region are respectively connected to the source region and the drain region.

A gate dielectric layer 12 is formed on an inner surface of the gate trench 11, for example, formed through a thermal process, atomic layer chemical vapor deposition, or in-situ steam oxidation. The gate dielectric layer 12 is in contact with the gate trench 11 and is adapted to the shape of the gate trench 11, forming a substantially uniformly thick film layer. The gate dielectric layer 12 does not fill up the gate trench 11, and the gate dielectric layer 12 disposed in the gate trench 11 also encloses to form a trench-like shape. The gate dielectric layer 12 can be made of a material comprising an insulating material, such as silicon oxide.

Step S200: forming a gate structure, the gate structure being disposed on the gate dielectric layer and filling the gate trench, and the gate structure comprising a metal layer and a conductive layer; where the metal layer comprises a plurality of first grains and second grains, the second grains being disposed on the first grains, the first grains and the second grains containing a same metallic element, and grain sizes of the second grains being smaller than grain sizes of at least a portion of the first grains; and where the conductive layer is disposed on the second grains, the conductive layer is isolated from the second grains with oxygen, and a side of the oxygen away from the first grains is in contact with the conductive layer.

With reference to FIG. 2 and FIG. 3, the gate structure is filled at the bottom of the gate trench 11, and a top surface of the gate structure is lower than a top surface of the substrate 10. The gate structure comprises a metal layer 20 and a conductive layer 30. The metal layer 20 comprises a plurality of first grains 21 and a plurality of second grains 22, the second grains 22 being disposed on the first grains 21.

In some examples, grain sizes of first grains 21 away from the second grains 22 are smaller than grain sizes of first grains 21 close to the second grains 22. The first grains 21 away from the second grains 22 is closer to the bottom of the gate trench 11, and since the size of the bottom of the gate trench 11 is relatively small, these first grains 21 with smaller grain sizes can be more suitable to fill the bottom of the gate trench 11.

Grain sizes of the first grains 21 gradually increase along a direction approaching the second grains 22. The direction approaching the second grains 22 is also a direction distancing from the bottom of the gate trench 11. The closer to the second grains 22, the larger the grain sizes of the first grains 21, thus, the grain sizes of the plurality of first grains 21 change gradually, providing good transition among the plurality of first grains 21.

The second grains 22 and the first grains 21 contain a same metallic element. In some examples, both the first grains 21 and the second grains 22 contain a tungsten element, providing good electrical characteristics for the metal layer 20. The grain sizes of the second grains 22 are smaller than grain sizes of at least a portion of the first grains 21, avoiding too large grain sizes of the second grains 22, thus allowing for a relatively dense arrangement and good planarity of the plurality of second grains 22, and facilitating formation of a film layer (such as the conductive layer 30) thereon.

As an example, the grain sizes of the second grains 22 are smaller than the grain sizes of all the first grains 21 in whole. As another example, the grain sizes of the second grains 22 are smaller than grain sizes of first grains 21 close to the second grains 22 and larger than grain sizes of first grains 21 away from the second grains 22. In this way, the grain sizes of the second grains 22 are larger than the grain sizes of the first grains 21 at the bottom of the gate trench 11, avoiding that the grain sizes of the second grains 22 are too small, and facilitating formation of the second grains 22. Meanwhile, the grain sizes of the second grains 22 are smaller than the grain sizes of the first grains 21 at the top of the gate trench 11, avoiding too large grain sizes of the second grains 22, and facilitating formation of a film layer thereon.

In some specific implementations, a first spacing S is provided between the second grains 22 and the isolation structure 14, and grain sizes of first grains 21 having a distance from the isolation structure 14 greater than or equal to a second spacing are larger than the grain sizes of the second grains 22, where the second spacing is half of the first spacing.

As shown in FIG. 3, the first spacing is provided between the surfaces facing each other of the second grains 22 and the isolation structure 14, the first spacing being indicated with S in FIG. 3. Considering an interface (indicated with M in FIG. 3) that is above the isolation structure 14 by a distance of half of the first spacing, the distance from the interface M to the isolation structure 14 is namely the second spacing. The grain sizes of the first grains 21 disposed on a side of the interface away from the isolation structure 14 are larger than the grain sizes of the second grains 22.

Further reference is made to FIG. 2 and FIG. 3, oxygen 23 is provided on a side of the second grains 22 away from the first grains 21, meaning that the oxygen 23 is at least disposed on the second grains 22. As an example, with reference to FIG. 4, the second grains 22 are surrounded by oxygen 23 to avoid a contact between the side of the second grains 22 away from the first grains 21 and other film layers, thereby reducing or avoiding reactions between the other film layers and the second grains 22, and ensuring the performance of the metal layer 20.

The conductive layer 30 is disposed on the second grains 22. For example, the conductive layer 30 is made of a material comprising polysilicon. The conductive layer 30 is isolated from the second grains 22 with oxygen 23, and a side of the oxygen 23 away from the first grains 21 is in contact with the conductive layer 30. Using the oxygen 23 to isolate the second grains 22 from the conductive layer 30, avoids the direct contact between the second grains 22 and the conductive layer 30, namely avoiding the direct contact between the metal layer 20 and the conductive layer 30, thus preventing the formation of metal silicides during the subsequent thermal processing, and reducing the gate induced drain leakage, thereby, improving the electrical characteristics of the gate structure, and enhancing the performance of the semiconductor device.

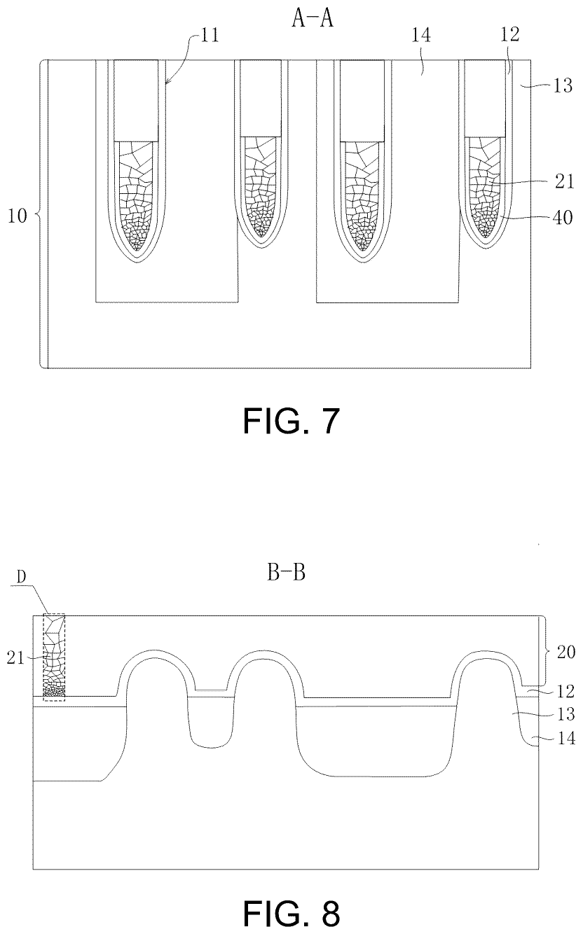

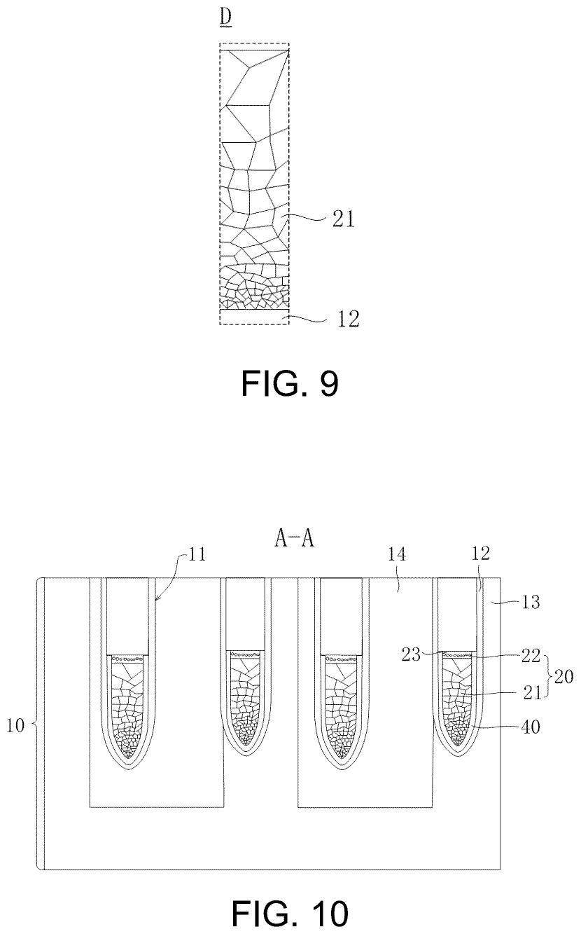

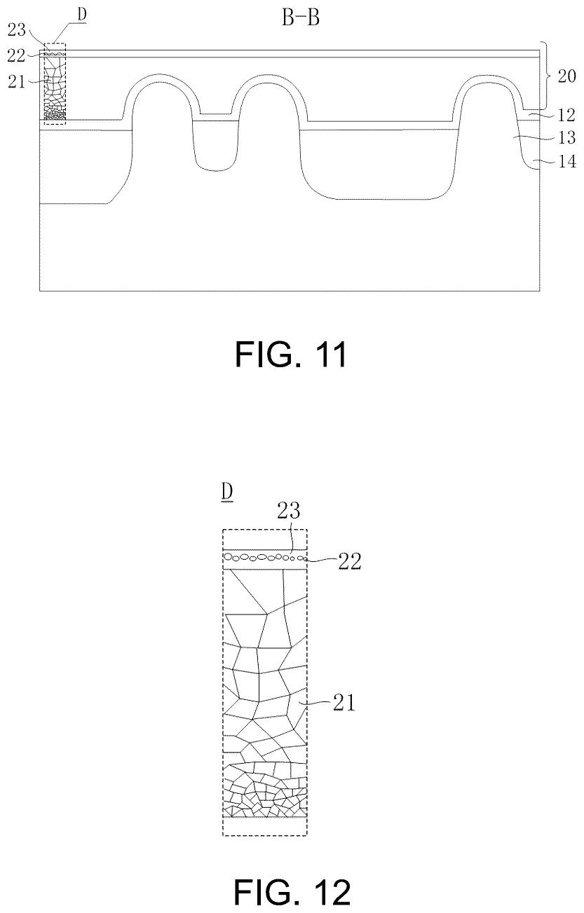

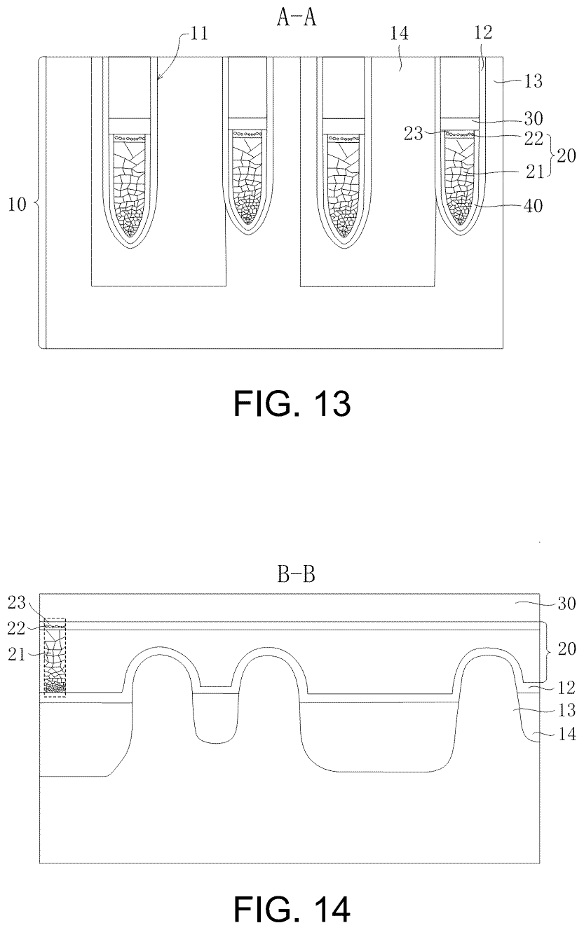

With reference to FIG. 6 to FIG. 14, FIG. 7 is a cross-sectional schematic diagram when first grains are formed according to an embodiment of the present disclosure; FIG. 8 is another cross-sectional schematic diagram when first grains are formed according to an embodiment of the present disclosure; FIG. 9 is a localized enlarged diagram of area D in FIG. 8; FIG. 10 is a cross-sectional schematic diagram when second grains are formed according to an embodiment of the present disclosure; FIG. 11 is another cross-sectional schematic diagram when second grains are formed according to an embodiment of the present disclosure; FIG. 12 is a localized enlarged diagram of area D in FIG. 11; FIG. 13 is a cross-sectional schematic diagram when a conductive layer is formed according to an embodiment of the present disclosure; and FIG. 14 is another cross-sectional schematic diagram when a conductive layer is formed according to an embodiment of the present disclosure. Among them, only the grain sizes of some areas are shown in FIG. 8 and FIG. 11.

In some possible implementations, forming the gate structure comprises: depositing to form the plurality of first grains 21 within the gate trench 11; performing an oxygen treatment process on surfaces of the plurality of first grains 21, for example, continuously introducing oxygen to the surfaces of the plurality of first grains 21, such that the second grains 22 are formed from first grains 21 away from a bottom of the gate trench 11, and the oxygen 23 is formed on the second grains 23; depositing the conductive layer 30 within the gate trench 11, the conductive layer 30 being in contact with the oxygen 23.

The second grains 22 are formed from first grains 21 away from a bottom of the gate trench 11 through an oxygen treatment process, and the oxygen 23 is formed on the second grains 22, such that the formation of the second grains 22 and the formation of the oxygen 23 can be achieved through a same process, which reduces the steps of the manufacturing method and easily ensures that the same metallic element is contained in the second grains 22 and the first grains 21, as well as the grain sizes of the second grains 22 and the first grains 21.

In some examples, with reference to FIG. 13, FIG. 14, FIG. 2 and FIG. 3, after the gate structure is formed, the method further comprises: forming the insulating cap layer 50, the insulating cap layer 50 being filled within the gate trench 11 and disposed on a side of the conductive layer 30 away from the metal layer 20. The insulating cap layer 50 is disposed atop the conductive layer 30, and the insulating cap layer 50 is made of a material comprising silicon nitride, or the like. A top surface of the insulating cap layer 50 is at least flush with a top surface of the substrate 10, to avoid an electric connection between a top surface of the gate structure and other film layers, ensuring the performance of the semiconductor device. The insulating cap layer 50 can be formed through a process such as chemical vapor deposition, atomic layer deposition, or the like.

In some examples, before forming the gate structure, the method further comprises: forming a metal nitride layer 40, the metal nitride layer 40 being disposed between the gate dielectric layer 12 and the metal layer 20. Using the metal nitride layer 40 to isolate the gate dielectric layer 12 from the metal layer 20 prevents the metal layer 20 from diffusing into the gate dielectric layer 12 and ensuring the performance of the gate dielectric layer 12. The metal nitride layer 40 is, for example, a titanium nitride layer..

The metal nitride layer 40 covers part of a surface of the gate dielectric layer 12, the metal nitride layer 40 forming a trench-like shape, and being disposed at the bottom of the gate trench 11. The metal nitride can be formed by deposition and etch-back. The metal layer 20 is disposed in the space enclosed by the metal nitride layer 40, and the conductive layer 30 is formed on the metal layer 20 and the metal nitride layer 40. Further, the insulating cap layer 50 is formed on the conductive layer 30.

The manufacturing method for a semiconductor device according to the embodiment of the present disclosure comprises: providing a substrate 10, where a gate trench 11 is formed in the substrate 10, and an inner surface of the gate trench 11 is covered with a gate dielectric layer 12; and forming a gate structure, the gate structure being disposed on the gate dielectric layer 12 and filling the gate trench 11. The gate structure comprises a metal layer 20 and a conductive layer 30, where the metal layer 20 comprises a plurality of first grains 21 and a plurality of second grains 22 disposed on the first grains 21. The first grains 21 and the second grains 22 contain a same metallic element to ensure the electrical performance of the metal layer 20. Grain sizes of the second grains 22 are smaller than grain sizes of at least a portion of the first grains 21, avoiding too large grain sizes of the second grains 22, thus facilitating formation of a film layer thereon. The conductive layer 30 is isolated from the second grains 22 with oxygen 23, and a side of the oxygen 23 away from the first grains 21 is in contact with the conductive layer 30. Using the oxygen 23 to isolate the second grains 22 from the conductive layer 30 avoids the direct contact between the second grains 22 and the conductive layer 30, and thus preventing a reaction between the conductive layer 30 and the metal layer 20 during the subsequent thermal processing to reduce the gate induced drain leakage, thereby, improving the electrical characteristics of the gate structure, and enhancing the performance of the semiconductor device.

The various embodiments or implementations in the present specification are described in a progressive manner, where each embodiment focuses on the differences from other embodiments, and for the same or similar parts between the various embodiments, cross reference may be made. The description of reference terms such as “an implementation”, “some implementations”, “illustrative implementations”, “examples”, “specific examples”, or “some examples” refers to the specific features, structures, materials, or characteristics described in conjunction with the implementations or examples being included in at least one implementation or example of the present disclosure. In the present specification, schematic representations of the foregoing terms do not necessarily refer to the same implementations or examples. Moreover, the specific features, structures, materials, or characteristics described can be combined in any one or more of the implementations or examples in a suitable manner.

Finally, it should be noted that the above embodiments are merely used to explain the technical solutions of the present disclosure, but are not intended to limit the present disclosure. Although the present disclosure has been described in detail with reference to the foregoing embodiments, those ordinarily skilled in the art should understand that modifications can be made to the technical solutions recorded in the foregoing embodiments, or some or all of the technical features thereof may be substituted by their equivalents, and such modifications or substitutions do not cause the nature of the corresponding technical solutions to deviate from the scope of the technical solutions of the embodiments of the present disclosure.

What is claimed is:

1. A semiconductor device, comprising:
a substrate;
a gate trench, being disposed in the substrate;
a gate dielectric layer, being disposed in the substrate and covering an inner surface of the gate trench; and
a gate structure, being disposed on the gate dielectric layer and filling the gate trench, wherein the gate structure comprises a metal layer and a conductive layer;
the metal layer comprises:
a plurality of first grains; and
a plurality of second grains, being disposed on the first grains, wherein the first grains and the second grains contain a same metallic element, and grain sizes of the second grains are smaller than grain sizes of at least a portion of the first grains;
the conductive layer is disposed on the second grains;
wherein the conductive layer is isolated from the second grains with oxygen, and a side of the oxygen away from the first grains is in contact with the conductive layer.

2. The semiconductor device according to claim 1, wherein the second grains are surrounded by the oxygen.

3. The semiconductor device according to claim 1, wherein the grain sizes of the first grains away from the second grains are smaller than the grain sizes of the first grains close to the second grains.

4. The semiconductor device according to claim 3, wherein the grain sizes of the first grains gradually increase along a direction approaching the second grains.

5. The semiconductor device according to claim 1, wherein the grain sizes of the second grains are smaller than the grain sizes of the first grains close to the second grains and larger than the grain sizes of the first grains away from the second grains.

6. The semiconductor device according to claim 5, wherein the substrate further comprises a plurality of active areas and an isolation structure isolating the active areas, and the gate trench extends through the active areas and the isolation structure;
a first spacing is provided between the second grains and the isolation structure, and the grain sizes of the first grains having a distance from the isolation structure greater than or equal to a second spacing are larger than the grain sizes of the second grains, the second spacing being half of the first spacing.

7. The semiconductor device according to claim 1, wherein both the first grains and the second grains contain a tungsten element, and the conductive layer is made of a material comprising polysilicon.

8. The semiconductor device according to claim 1, further comprising a metal nitride layer, the metal nitride layer being disposed between the gate dielectric layer and the metal layer.

9. The semiconductor device according to claim 1, further comprising an insulating cap layer, the insulating cap layer being filled within the gate trench and disposed on a side of the conductive layer away from the metal layer.

10. A manufacturing method for a semiconductor device, comprising:
providing a substrate, wherein a gate trench is formed in the substrate, and an inner surface of the gate trench is covered with a gate dielectric layer;
forming a gate structure, the gate structure being disposed on the gate dielectric layer and filling the gate trench, and the gate structure comprising a metal layer and a conductive layer; wherein the metal layer comprises a plurality of first grains and second grains, the second grains being disposed on the first grains, the first grains and the second grains containing a same metallic element, and grain sizes of the second grains being smaller than grain sizes of at least a portion of the first grains; and wherein the conductive layer is disposed on the second grains, the conductive layer is isolated from the second grains with oxygen, and a side of the oxygen away from the first grains is in contact with the conductive layer.

11. The manufacturing method according to claim 10, wherein the second grains are formed from the first grains away from a bottom of the gate trench through an oxygen treatment process, and the oxygen is formed on the second grains.

12. The manufacturing method according to claim 10, wherein the second grains are surrounded by the oxygen.

13. The manufacturing method according to claim 10, wherein the grain sizes of the first grains away from the second grains are smaller than the grain sizes of the first grains close to the second grains.

14. The manufacturing method according to claim 13, wherein the grain sizes of the first grains gradually increase along a direction approaching the second grains.

15. The manufacturing method according to claim 10, wherein the grain sizes of the second grains are smaller than the grain sizes of the first grains close to the second grains and larger than the grain sizes of the first grains away from the second grains.

16. The manufacturing method according to claim 15, wherein the substrate further comprises a plurality of active areas and an isolation structure isolating the active areas, and the gate trench extends through at least one of the active areas;
a first spacing is provided between the second grains and the isolation structure, and the grain sizes of the first grains having a distance from the isolation structure greater than or equal to a second spacing are larger than the grain sizes of the second grains, the second spacing being half of the first spacing.

17. The manufacturing method according to claim 10, wherein both the first grains and the second grains contain a tungsten element, and the conductive layer is made of a material comprising polysilicon.

18. The manufacturing method according to claim 10, further comprising: forming a metal nitride layer, the metal nitride layer being disposed between the gate dielectric layer and the metal layer.

19. The manufacturing method according to claim 10, further comprising: forming an insulating cap layer, the insulating cap layer being filled within the gate trench and disposed on a side of the conductive layer away from the metal layer.
